(19) United States
(12) Patent Application Publication
(10) Pub. No.: US 2007/0214300 A1
(43) Pub. Date: Sep. 13, 2007

(54) Agricultural communication system

(75) Inventors: Noel Wayne Anderson, Fargo, ND (US); Mark William Stelford, Sycamore, IL (US); Stephen Michael Faivre, Kingston, IL (US)

Correspondence Address: DEERE & COMPANY, ONE JOHN DEERE PLACE, MOLINE, IL, 61265, US

(73) Assignee: Deere & Company, a Delaware corporation

(21) Appl. No.: 11/371,763

(22) Filed: Mar. 9, 2006

(51) Int. Cl. G06F 13/00; H05K 7/10

(52) U.S. Cl. 710/301

(57) ABSTRACT

A mobile agricultural vehicle including a frame, a motor carried by the frame, a standalone data processing assembly, a sensor and a plug-in card. The standalone data processing assembly has a data interface but is without communications capability. The standalone data processing assembly is mounted to the frame. The sensor is coupled to the standalone data processing assembly, the sensor generating a signal that is used by the standalone data processing assembly. The plug-in card interfaces with the data interface and has a processor, a memory and a network interface device. The memory is accessible by the processor and by the standalone data processing assembly. The network interface device transmits and receives information, the information being accessed in the memory by the processor transparent to the standalone data processing assembly.

### FIELD OF THE INVENTION

The present invention relates to an agricultural communication system, and, more particularly to an agricultural data communication system.

### BACKGROUND OF THE INVENTION

Over the years data gathering instruments have been incorporated and retrofit into agricultural equipment. Instruments were developed and adapted for use with agricultural equipment, such as a harvester/combine. Such an agricultural instrument would include a agricultural yield monitor, which may be utilized in a combine for the detection of the yield per acre of the crop being harvested. Such a grain yield monitor is disclosed in U.S. Pat. No. 5,282,389, which discloses a system for measuring flow pressure of conveying clean yield product and for converting this pressure data to a meaningful flow rate signal and to generate a field yield map. Such a yield monitor, may be incorporated into a combine when it is being produced or a retrofit kit may be utilized to instrument the combine.

As the evolution of agricultural instrumentation has progressed data interfaces were incorporated into the agricultural instrumentation. Such data interfaces allowed for the insertion of memory cards, such as PCMCIA cards so that information could be stored thereon. The information is gathered in the field and/or the information contained on the memory card can be utilized in some aspect of the agricultural equipment operational performance in the field.

Advances in the instrumentation of agricultural equipment has taken place, which has tended to obsolete the legacy agricultural instrumentation system. A legacy system as referred to herein is used to denote an agricultural electrical assembly that accepts a memory card but does not otherwise communicate with a computer or network system.

What is needed in the art is a device that will allow the use of legacy electrical instrumentation systems with the integrated modernized systems in a cost effective manner.

### SUMMARY OF THE INVENTION

The present invention consists of a mobile agricultural vehicle including a frame, a motor carried by the frame, a standalone data processing assembly, a sensor and a plug-in card. The standalone data processing assembly has a data interface but is without communications capability. The standalone data processing assembly is mounted to the frame. The sensor is coupled to the standalone data processing assembly, the sensor generating a signal that is used by the standalone data processing assembly. The plug-in card interfaces with the data interface and has a processor, a memory and a network interface device. The memory is accessible by the processor and by the standalone data processing assembly. The network interface device transmits and receives information, the information being accessed in the memory by the processor transparent to the standalone data processing assembly.

### BRIEF DESCRIPTION OF THE DRAWINGS

FIG. 1 shows an embodiment of a communication interface system of the present invention being inserted into a legacy agricultural instrument;

FIG. 2 illustrates in a schematic manner elements of the communication interface system of FIG. 1; and

FIG. 3 illustrates the use of the communication interface system of FIGS. 1 and 2 relative to agricultural equipment.

### DESCRIPTION OF THE PREFERRED EMBODIMENT

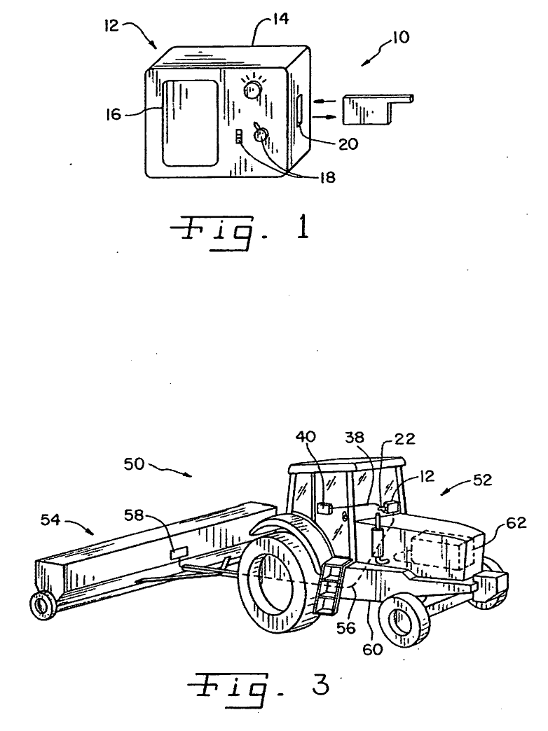

Referring now to the drawings, and more particularly to FIG. 1, there is shown a communication interface system 10 being inserted into a legacy agricultural electrical assembly 12. A legacy agricultural electrical assembly 12 specifically refers to agricultural instrumentation that is primarily utilized for data gathering and/or control of a piece of equipment as it is being utilized in field operations. The word ‘legacy’ specifically refers to the instrumentation as being dated and of a standalone nature without the capability of networking or communicating with other electronic instrumentation. Legacy agricultural electrical assembly 12 includes a housing 14, a display 16, controls 18 and a PCMCIA interface 20. Housing 14 is mounted in a secure manner to an agricultural piece of equipment such as a tractor or a combine. Display 16 provides information to the operator relative to some function that is being measured on the agricultural equipment, such as yield, speed, planting density, etc. Controls 18 allow selective changes in the functionality of legacy assembly 12, such as changing the type of information sent to display 16. PCMCIA interface 20 is utilized to provide data that can be read by legacy assembly 12 and a storage medium upon which legacy assembly 12 may store information. Legacy assembly 12 is a standalone data gathering assembly 12 and is utilized in field operations utilizing data contained on a card placed in PCMCIA interface 20, such as fertilizer needs based upon position of the equipment or other information specifically related to a certain locale within the field. Grain yield data based on the position can also be stored in a similar fashion upon a PCMCIA card inserted into PCMCIA interface 20. Legacy agriculture electrical assembly 12 lacks communication and networking capability and the sophistication that deals with such protocols. Legacy assembly 12 very specifically is directed toward one function or one group of functions in a standalone manner.

Legacy assembly 12, as used in its standalone mode apart from the present invention, reads and/or stores information in a non-volatile memory contained on a PCMCIA card inserted into interface 20. The information may be related to the delivery of a product, such as a chemical, that is to be delivered in a geographically sensitive quantity. Legacy assembly 12 utilizes positional information from a location determining circuit, such as a global positioning circuit, and couples that with information in the memory to deliver the product in a quantity that is dependent upon the location. In a similar manner, legacy assembly 12 can write information to the memory that may be related to the geographical location, such as a crop yield. The information read from and/or written to the memory is then later physically transferred by a user that removes the PCMCIA card and inserts it into a processing device such as a computer.

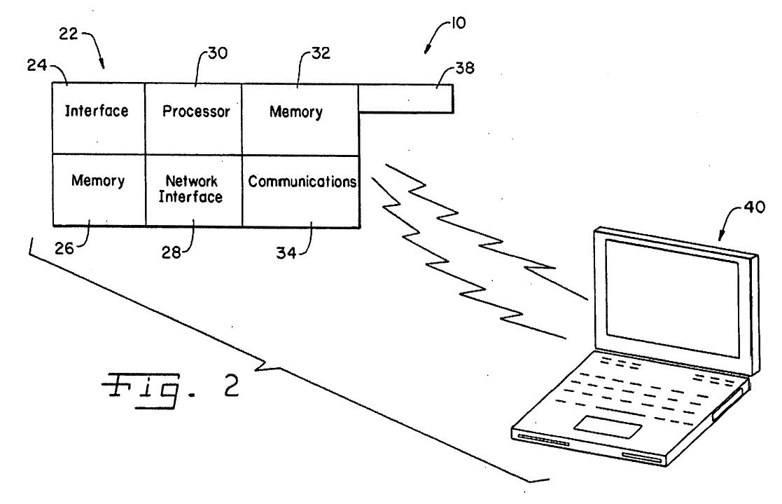

Now, additionally referring to FIG. 2, there are shown further details of communication interface system 10. Communication interface system 10 includes a circuit card 22, also known as a PCMCIA card 22 that includes interface circuitry 24, a memory 26, an external network interface 28, a gateway processor 30, a gateway memory 32 and communication circuitry 34. The elements of circuit card 22 are communicatively interconnected and FIG. 2 is a schematical representation not intended to infer the physical location of any of the elements thereon nor any limitation relative to their connections to each other. Interface circuitry 24 interacts with legacy assembly 12 allowing access by legacy assembly 12 to memory 26. Legacy assembly 12 can thereby read and write information contained in memory 26 in a manner identical to how legacy assembly 12 functions apart from the present invention as discussed in the previous paragraph. External network interface 28 allows gateway processor 30 to send and receive information by a network protocol. The information may be sent by way of a wired connection or in a wireless manner by way of communication circuits 34.

Gateway processor 30 interacts with memory 26 and gateway memory 32. Information stored in gateway memory 32 is not accessible by legacy assembly 12, since legacy assembly 12 functions without any interfering interaction with gateway processor 30, gateway memory 32, external network interface 28 or communication circuitry 34. Gateway processor 30 interacts with memory 26 in a manner that is transparent to legacy assembly 12. Information in memory 26 may be accessed by legacy assembly 12 and by gateway processor 30 in a single memory cycle, thereby making the access of memory 26 by gateway processor 30 transparent to legacy assembly 12. Another manner of transparently interfacing with memory 26, is to queue read/write requests by gateway processor 30 so that they do not conflict with read/write operations by legacy assembly 12.

A communication link 38, which may be in the form of a cable 38 that is removably connected to external network interface 28, or an antenna 38 connected to communications circuits 34, convey data and information from circuit card 22 to a computer 40. Computer 40 may be remote from communication interface system 10 and information transmitted to and from communication interface system 10 can be utilized to update information in memory 26. For example, information about the field in which legacy assembly 12 is gathering or utilizing data can be stored, removed or updated as information is communicated over communication link 38 to memory 26 by way of gateway processor 30. Alternatively, computer 40 can be a Field/Farm Network Information System (FNIS) node, which conveys and receives information relative to the field/farm in which the present invention is being used.

Now, additionally referring to FIG. 3 there is shown a mobile agricultural equipment system 50, which may include a tractor 52 and a planter 54. Tractor 52 includes a frame 60 with a motor 62 attached thereto. Legacy agricultural electrical assembly 12 is mounted to a part of frame 60 and is connected by way of legacy cabling 56 to sensors 58 in planter 54, which may detect seed discharge rates of planter 54. The seed discharge information is conveyed by way of a signal through legacy cabling 56 to legacy assembly 12. It is to be understood that agricultural system 50 is illustrative in nature and the present invention is not confined to a tractor/planter configuration. Legacy system 12 functions as it was originally designed while information is conveyed by way of circuit card 22 that is hardwired to an onboard computer 40 by way of communications cable 38 connected between external network interface 28 and computer 40. Legacy agricultural electrical assembly 12 can be a distributed system and is not necessarily integrated as illustrated, but is illustrated in this manner for purposes of clarity. That data which legacy assembly 12 has stored is usable only after the physical removal of the storage medium from legacy assembly 12 and the transfer of the data to a data processing device (not illustrated). Further, application prescriptions, such as fertilizer application rates, cannot be received from sources external to legacy assembly 12 except by a physical removal, reprogramming and reinsertion of a memory card.

Communication interface system 10 allows the utilization of legacy assemblies 12, while allowing memory 26 to be addressed on a real time basis, by communication interface system 10 without altering legacy assembly 12. Communication interface system 10 is backward compatible with a PCMCIA card, which legacy system 12 would normally operate with. The incorporation of communication interface system 10 allows on the go alterations in data contained in memory 26 completely transparent to the operation of legacy system 12. Alternatively, an identification sequence, circuitry or mechanic device may be present in assembly 10 to identify communication interface system 10, thereby allowing a system, more sophisticated than legacy assembly 12, connected to assembly 10 to directly use the services of assembly 10.

Having described the preferred embodiment, it will become apparent that various modifications can be made without departing from the scope of the invention as defined in the accompanying claims.

1. A mobile agricultural vehicle, comprising:
a frame;
a motor carried by said frame;
a standalone data processing assembly having a data interface but without communications capability, said standalone data processing assembly mounted to said frame;
a sensor coupled to said standalone data processing assembly, said sensor generating a signal that is used by said standalone data processing assembly;
a plug-in card that interfaces with said data interface, said plug-in card having:
a processor;
a memory accessible by said processor and by said standalone data processing assembly; and
a network interface device that transmits and receives information, said information being accessed in said memory by said processor transparent to said standalone data processing assembly.

2. The mobile agricultural vehicle of claim 1, further comprising an other memory only accessible by said processor.

3. The mobile agricultural vehicle of claim 2, further comprising a communications device that at least one of transmits and receives said information.

4. The mobile agricultural vehicle of claim 3, wherein said communications device is a wireless communication device.

5. The mobile agricultural vehicle of claim 1, wherein said plug-in card is identifiable as having capabilities other than data storage, but not by said standalone data processing assembly.

6. The mobile agricultural vehicle of claim 1, further comprising a computer attached to the vehicle, said computer in communication with said processor.

7. An agricultural electrical assembly for use in a mobile agricultural vehicle having a motor attached to a frame, the assembly comprising:
a standalone data processing assembly having a data interface but without communications capability, said standalone data processing assembly being attached to the frame;
a plug-in card that interfaces with said data interface, said plug-in card having:
a processor;
a memory accessible by said processor and by said standalone data processing assembly; and
a network interface device that transmits and receives information, said information being accessed in said memory by said processor transparent to said standalone data processing assembly.

8. The agricultural electrical assembly of claim 7, further comprising an other memory only accessible by said processor.

9. The agricultural electrical assembly of claim 8, further comprising a communications device that at least one of transmits and receives said information.

10. The agricultural electrical assembly of claim 9, wherein said communications device is a wireless communication device.

11. The agricultural electrical assembly of claim 7, wherein said plug-in card is identifiable as having capabilities other than data storage, but not by said standalone data processing assembly.

12. The agricultural electrical assembly of claim 7, wherein said standalone data processing assembly is mountable to a mobile agricultural apparatus.

13. A method of interfacing with a legacy agricultural electrical assembly installed in a mobile agricultural vehicle, comprising the steps of:
removably connecting a memory to the assembly;
at least one of reading and writing information to said memory by the legacy agricultural electrical assembly; and
transparently accessing said memory with a processor so as to not disturb the operation of the assembly.

14. The method of claim 13, wherein said memory is nonvolatile memory.

15. The method of claim 13, wherein said transparently accessing step includes accessing said memory by a processor interface and said processor in one memory cycle.

16. The method of claim 13, wherein said transparently accessing step includes queuing read and write requests to said memory.

17. The method of claim 13, wherein said memory and said processor are communicatively coupled and are detachable from the assembly.

18. The method of claim 17, further comprising the step of communicating said information to said processor from a computer.

19. The method of claim 18, wherein said communicating step is carried out in a wireless manner.

20. The method of claim 18, wherein both the legacy electrical assembly and said computer are mounted on the agricultural vehicle.
